(19) United States
(12) Patent Application Publication
(10) Pub. No.: US 2005/0237106 A1
(43) Pub. Date: Oct. 27, 2005

(54) Constant-current generating circuit

(75) Inventor: Nobuhiro Tomari, Miyazaki (JP)

Correspondence Address: NIXON PEABODY, LLP, 401 9TH STREET, NW, SUITE 900, WASHINGTON, DC, 20004-2128, US

(73) Assignee: Oki Electric Industry Co., Ltd., Tokyo (JP)

(21) Appl. No.: 11/057,240

(22) Filed: Feb. 15, 2005

(30) Foreign Application Priority Data
Apr. 22, 2004 (JP) 2004-126540

(51) Int. Cl. G11C 8/00

(52) U.S. Cl. 327/543

(57) ABSTRACT

A reference potential vr is applied to the gate of an NMOSFET 1a, and a potential Vn at a node N3 connected to an end of a reference resistor 5 is applied to the gate of an NMOSFET 1b. A PMOSFET 4 in series with the reference resistor 4 and a PMOSFET 4 forms a current mirror circuit. A load circuit 9 is connected in series with a PMOSFET 8 which forms a mirror circuit in combination with the PMOSFET 4. When the potential Vn is higher than the reference potential Vr, the source-drain conductance of the PMOSFET 1a increases, and the potential at the gate of the PMOSFET 4 rises, causing the current flowing through the PMOSFET 4 to decrease, and the potential Vn at the node N3 is lowered. The configuration of the circuit is simplified, and the response speed is increased.

### BACKGROUND OF THE INVENTION

The present invention relates to constant-current generating circuits, in particular, those formed of semiconductor integrated circuits.

FIG. 1 shows a conventional constant-current generating circuit. It comprises an operational amplifier 20 and a constant current section generating a predetermined current, and an output section supplying a constant current to a load circuit 39.

The operational amplifier 20 has n-channel MOS field-effect transistors (hereinafter referred to as “NMOSFETs”) 21a and 21b in a differential input stage, and the gate of the NMOSFET 21a, which forms a non-inverting input terminal of the operational amplifier 20, is connected to receive a reference potential Vr. The drains of the NMOSFETs 21a and 21b are connected respectively through p-channel MOS field-effect transistors (hereinafter referred to as “PMOSFETs”) 22a and 22b to a power supply Vdd. The gates of the PMOSFETs 22a and 22b are connected to the drain of the NMOSFET 21a. The sources of the NMOSFETs 21a and 21b are connected to the ground Vss via an NMOSFET 23 with its gate supplied with a bias potential Vb1.

The drain of the NMOSFET 21b is connected to the gate of a PMOSFET 24 in an output stage, and the source and the drain of the PMOSFET 24 are respectively connected to the power supply Vdd and the node N1 forming an output terminal. The node N1 is connected to the ground Vss via an NMOSFET 25 having its gate supplied with a bias potential Vb2. The node N1 is also connected to the drain of the NMOSFET 21b via a resistor 26 and a capacitor 27 for phase compensation.

The node N1 is also connected to the gate of a PMOSFET 31 forming a constant current section, and the source of the PMOSFET 31 is connected to the power supply Vdd. The drain of the PMOSFET 31 is connected to a node N2, which is connected to the ground Vss via a reference resistor 32, and to the gate of the NMOSFET 21b forming an inverting input terminal of the operational amplifier 20.

The node N1 is also connected to the gate of a PMOSFET 33 in the output section, and the PMOSFET 33 and the PMOSFET 31 in the constant current section form a current mirror circuit. The source of the PMOSFET 33 is connected to the power supply Vdd, and a load circuit 39 is connected between the drain of the PMOSFET 33 and the ground Vss.

In the constant-current generating circuit shown in FIG. 1, a reference potential Vr is supplied to the gate of the NMOSFET 21a forming the non-inverting input terminal of the operational amplifier 20, and conduction state of the PMOSFET 31 is controlled by the potential at the node N1 forming the output terminal, and the potential at the drain of the PMOSFET 31, i.e., the potential at the node N2 is negatively fed back to the gate of the NMOSFET 21b forming the inverting input terminal of the operational amplifier 20.

When the potential at the node N2 is higher than the reference potential Vr, the source-to-drain conductance of the NMOSFET 21b becomes larger than the source-to-drain conductance of the NMOSFET 21a, and the gate potential of the PMOSFET 24 is lowered. As a result, the potential at the node N1 rises, and the current flowing through the PMOSFET 31 is reduced, and the potential at the node N2 is lowered.

Conversely, when the potential at the node N2 is lower than the reference potential Vr, the source-to-drain conductance of the NMOSFET 21b becomes smaller than the source-to-drain conductance of the NMOSFET 21a, and the gate potential of the PMOSFET 24 is increased. As a result, the potential at the node N1 is lowered, and the current flowing through the PMOSFET 31 is increased, and the potential at the node N2 is raised.

By means of the negative feed back, the potential at the node N2 is kept equal the reference potential Vr. If the resistance of the reference resistor 32 is denoted by R, the current flowing through the reference resistor 32 is kept at Vr/R. The PMOSFET 31 and the PMOSFET 33 form a current mirror circuit, and if the mirror ratio is denoted by n, the current flowing through the PMOSFET 33 is kept at nVr/R, and this constant current is supplied to the load circuit 39.

The conventional constant-current generating circuit has the following problems:

There is an output stage formed of the PMOSFET 24 and the NMOSFET 25 following the differential input stage of the operational amplifier 20, and the constant current section formed of the PMOSFET 31 and the reference resistor 32 is connected at the output side of the operational amplifier 20, so that the size of the overall circuit is large, and the load on the power supply is relatively large.

Moreover, if the load is increased, the capacitance of the capacitor 27 for phase compensation needs to be increased, and the resistance of the resistor 26 for phase compensation needs to be reduced, so that the size of the overall circuit is increased.

Furthermore, the output of the differential input stage is transmitted through the output stage and the constant current section to the node N2, and the potential at the node N2 is fed back to the inverting input terminal of the operational amplifier 20. As a result, the feed back control action is slow, and the delay time from the establishment of the reference potential till the establishment of the constant current is long.

### SUMMARY OF THE INVENTION

Accordingly, it is an object of the invention to simplify the circuit configuration and to increase the response speed of the constant-current generating circuit.

According to the invention, there is provided a constant-current generating circuit including:
a first transistor of a first conductivity type having a first main electrode, a second main electrode, and a control electrode to which a reference potential is applied;
a second transistor of said first conductivity type having a first main electrode, a second main electrode, and a control electrode connected to an internal node;
a third transistor of a second conductivity type having a first main electrode connected to a first power supply node, a second main electrode connected to the second main electrode of said first transistor, and a control electrode connected to the second main electrode of said second transistor;
a fourth transistor of said second conductivity type having a first main electrode connected to the first power supply node, and a second main electrode and a control electrode connected to said second main electrode of said second transistor;
a fifth transistor of said first conductivity type having a first main electrode connected to a second power supply node, and a second main electrode connected to the first main electrodes of the first and second transistors;
a sixth transistor of said second conductivity type having a first main electrode connected to said first power supply node, a second main electrode connected to said internal node, and a control electrode connected to said second main electrode of said first transistor;
a reference resistor connected between said internal node and said second power supply node; and
a seventh transistor of said second conductivity type having a first main electrode connected to said first power supply node, and a second main electrode for connection with one end of a load circuit, the other end of which is connected to said second power supply node;
said seventh transistor also having a control electrode connected to said control electrode of said sixth transistor so that said sixth and seventh transistors together form a current mirror circuit.

The first to seventh transistors may be MOSFETs or bipolar transistors.

When the first to sevenths transistors are MOSFETs, n-channel MOSFETs may be used as transistors of a first conductivity type, and p-channel MOSFETs may be used as transistors of a second conductivity type. Sources and drains of MOSFETs are respectively used as first and second main electrodes of the transistors, while gates of the MOSFETs are used as control electrodes of the transistors.

When the first to seventh transistors are bipolar transistors, NPN transistors may be used as transistors of a first conductivity type, and PNP transistors may be used as transistors of a second conductivity type. Emitters and collectors of bipolar transistors are respectively used as first and second main electrodes of the transistors, while bases of the bipolar transistors are used as control electrodes of the transistors.

### BRIEF DESCRIPTION OF THE DRAWINGS

In the drawings;—

FIG. 1 is a circuit diagram showing a conventional constant-current generating circuit;

FIG. 2 is a circuit diagram showing a constant-current generating circuit according to Embodiment 1 of the present invention;

FIG. 3 is a circuit diagram showing a constant-current generating circuit according to Embodiment 2 of the present invention;

FIG. 4 is a circuit diagram showing a constant-current generating circuit according to Embodiment 3 of the present invention;

FIG. 5 is a circuit diagram showing a constant-current generating circuit according to Embodiment 4 of the present invention; and

FIG. 6 is a circuit diagram showing a constant-current generating circuit according to Embodiment 5 of the present invention.

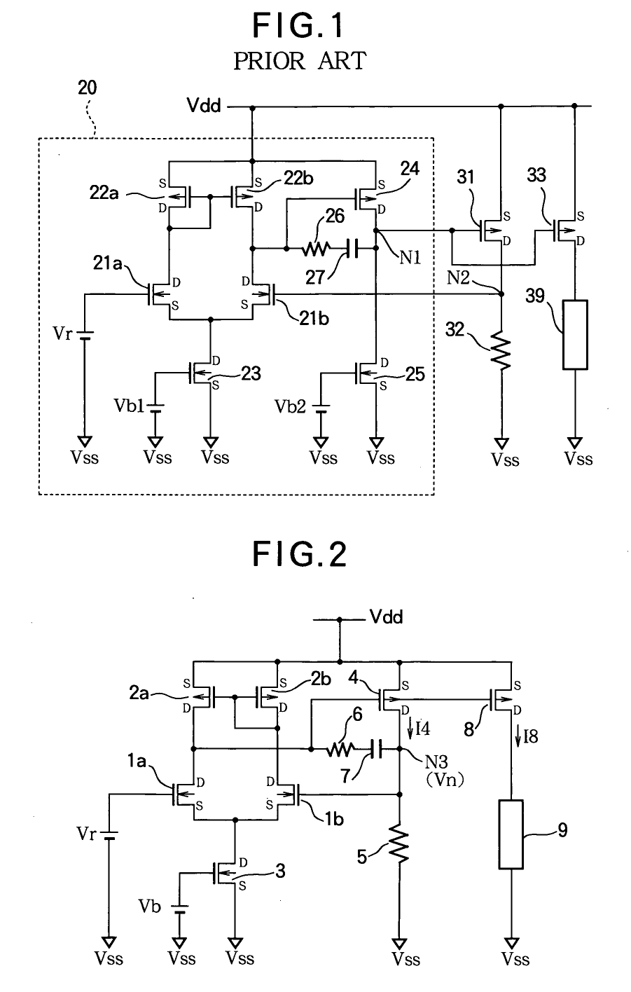

### DETAILED DESCRIPTION OF THE PREFERRED EMBODIMENT

### Embodiment 1

FIG. 2 shows a constant-current generating circuit according Embodiment 1 of the present invention. The illustrated constant-current generating circuit has a differential input stage including a pair of NMOSFETs 1a and 1b. The gate of the NMOSFET 1a is connected to receive a reference potential Vr. The drains of the NMOSFETs 1a and 1b are respectively connected to the drains of PMOSFETS 2a and 2b, and the sources of the PMOSFETs 2a and 2b are connected to a power supply node Vdd, also called a first power supply node. The sources of the NMOSFETs 1a and 1b are connected to the drain of an NMOSFET 3 having its gate connected to receive a bias potential Vb and having its source connected to the ground Vss, also called a second power supply node. The first power supply node Vdd supplies a potential, also identified by Vdd, which is higher than the potential, identified by Vss, by the second power supply node Vss.

The gates of the PMOSFETs 2a and 2b are connected to the drain of the NMOSFET 1b.

The drain of the NMOSFET 1a is connected to the gate of a PMOSFET 4 in an output stage, and the source of the PMOSFET 4 is connected to the power supply node Vdd. The drain of the PMOSFET 4 is connected to an internal node N3, which is connected via a reference resistor 5 to the ground Vss, and is also connected to the drain of the NMOSFET 1a, via a series circuit of a resistor 6 and a capacitor 7 for phase compensation.

The constant-current generating circuit also includes a PMOSFET 8 which, together with the PMOSFET 4 in the output stage, forms a current-current mirror circuit. The source of the PMOSFET 8 is connected to a power supply node Vdd, and the gate of the PMOSFET 8 is connected to the drain of the NMOSFET 1a, as is the gate of the PMOSFET 4. A load circuit 9 is connected between the drain of the PMOSFET 8 and the ground Vss.

Now the operation of the circuit is described.

A reference potential Vr is supplied to the gate of the NMOSFET 1a and a potential Vn at the internal node N3 is supplied to the gate of the NMOSFET 1b. By means of the potential at the drain of the NMOSFET 1a, the conduction of the PMOSFET 4 in the output stage is controlled, and the potential at the internal node N3 is maintained to be equal to the reference potential Vr.

If, for instance, the potential Vn at the internal node N3 becomes higher than the reference potential Vr, the current flowing through the NMOSFET 1b becomes larger, and hence, the current flowing through the NMOSFET 1a becomes smaller (because the NMOSFET 3 serves as a constant current source), and the drain potential of the NMOSFET 1a, and hence the gate potential of the PMOSFET 4 rises. As a result, the source-to-drain conductance of the PMOSFET 4 is reduced, and the potential Vn at the internal node N3 is lowered.

If, on the other hand, the potential Vn at the internal node N3 becomes lower than the reference potential Vr, the current flowing through the NMOSFET 1b becomes smaller, and hence, the current flowing through the NMOSFET 1a becomes larger (because the NMOSFET 3 serves as a constant current source), and the drain potential of the NMOSFET 1a, and hence the gate potential of the PMOSFET 4 is lowered. As a result, the source-to-drain conductance of the PMOSFET 4 is enlarged, and the potential Vn at the internal node N3 is increased.

By means of the negative feedback described above, the potential Vn at the internal node N3 is controlled to be equal to the reference potential Vr. The current I4 flowing through the PMOSFET 4 and the reference resistor 5 is maintained to be a constant value given by
I4=Vr/R
where R represents the resistance of the reference resistor 5. Sine the PMOSFET 4 and the PMOSFET 8 form a current mirror circuit, the current I8 flowing through the PMOSFET 8 is kept constant at a value given by
   I8=n8×Vr/R
where n8 represents the mirror ratio of the current mirror circuit formed of the PMOSFETs 4 and 8.

This current I8 of a value n8×Vr/R flows through the load circuit 9.

As has been described, in the constant-current generating circuit according to Embodiment 1, the potential difference detected at the differential input stage is supplied to the gate of a PMOSFET 4, and the potential at the node N3 connecting the PMOSFET 4 and the reference resistor 5 is fed back to the amplifier stage.

In this way, the configuration of the circuit is simplified. Moreover, the load on the differential input stage is reduced, so that the phase delay is reduced, and the resistance of the resistor 6 can be increased, and the capacitance of the capacitor 7 can be reduced, and the size of the circuit can be reduced.

Moreover, because the potential Vn at the internal node N3 in the output stage is directly fed back to the differential input stage, the response speed is increased.

### Embodiment 2

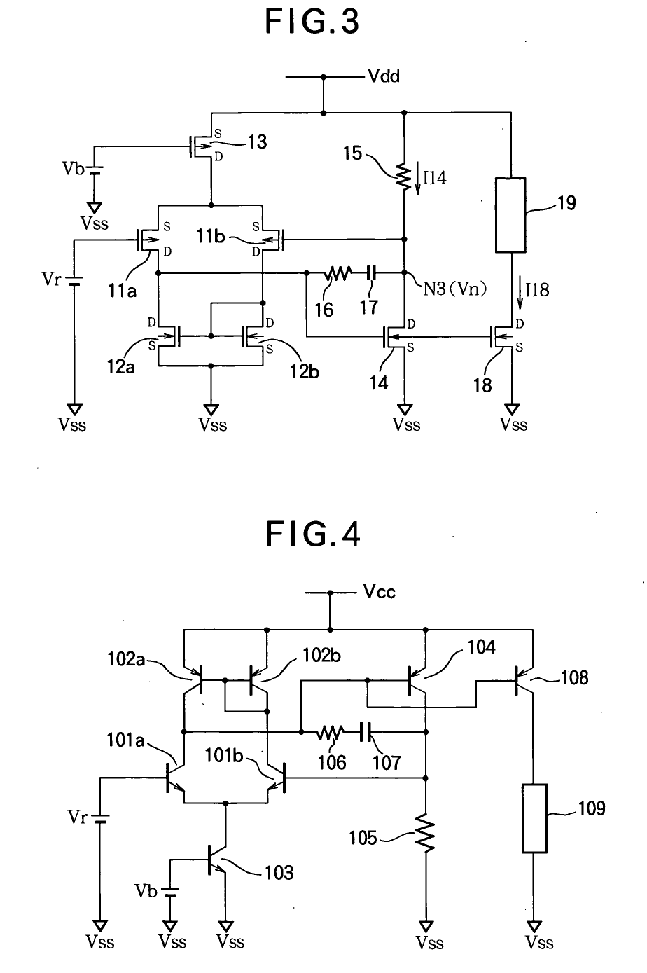

FIG. 3 shows a constant-current generating circuit according to Embodiment 2 of the present invention. The constant-current generating circuit shown in FIG. 3 is similar to that shown in FIG. 2, but the polarities of the potentials of the power supply nodes have been reversed, PMOSFETs in FIG. 2 have been replaced with NMOSFESTs, and NMOSFETs in FIG. 2 have been replaced with PMOSFETs.

The constant-current generating circuit in FIG. 3 has a differential input stage including a pair of PMOSFETs 11a and 11b. The gate of the PMOSFET 11a is connected to receive a reference potential Vr. The drains of the PMOSFETs 11a and 11b are respectively connected to the drains of NMOSFETS 12a and 12b, and the sources of the NMOSFETs 12a and 12b are connected to the ground Vss. The sources of the PMOSFETs 11a and 11b are connected to the drain of a PMOSFET 13 having its gate connected to receive a bias potential Vb and having its source connected to a power supply node Vdd. In this embodiment, the ground Vss serves as a first power supply node, and the power supply node Vdd serves as a second power supply node, for the reason which will be clear from the following description of the operation. The first power supply node (Vss) of this embodiment provides a potential lower than the second power supply node (Vdd).

The gates of the NMOSFETs 12a and 12b are connected to the drain of the PMOSFET 11b.

The drain of the PMOSFET 11a is connected to the gate of an NMOSFET 14 in an output stage, and the source of the NMOSFET 14 is connected to the ground. The drain of the NMOSFET 14 is connected to an internal node N3, which is connected via a reference resistor 15 to the power supply node Vdd. The internal node N3 is also connected to the drain of the PMOSFET 11a, via a series circuit of a resistor 16 and a capacitor 17 for phase compensation.

The constant-current generating circuit also includes an NMOSFET 18 which, together with the NMOSFET 14 in the output stage, forms a current-current mirror circuit. The source of the NMOSFET 18 is connected to the ground Vss, and the gate of the NMOSFET 18 is connected to the drain of the PMOSFET 11a, as is the gate of the NMOSFET 14. A load circuit 19 is connected between the drain of the NMOSFET 18 and the power supply node Vdd.

The operation of the circuit shown in FIG. 3 is similar to that described with reference to FIG. 2.

However, the current I14 flowing through the reference resistor 15 is given by
I14=(Vdd−Vr)/R
where R represents the resistance of the reference resistor 15.

The current I18 flowing through the NMOSFET 18 and the load circuit 19 is given by:
I18=n18×(Vdd−Vr)/R.
where n18 represents the mirror ratio of the current mirror circuit formed of the NMOSFETs 14 and 18.

Advantages of Embodiment 2 are similar to those of Embodiment 1.

### Embodiment 3

FIG. 4 shows a constant-current generating circuit according Embodiment 3 of the present invention. The circuit of FIG. 4 is similar to the circuit of FIG. 2, but bipolar transistors 101a-108 are used in place of MOSFETs 1a to 8. Specifically, NPN transistors are used in place of NMOSFETs, as transistors of a first conductivity type, and PNP transistors are used in place of PMOSFETs, as transistors of a second conductivity type. Emitters, collectors and bases of the bipolar transistors are used for connection in place of sources, drains and gates of the MOSFETs. The first power supply node in FIG. 4 is now denoted by Vcc, while the second power supply node is identified by the same reference (Vss).

The operation of the circuit of FIG. 4 is similar to that of the circuit of FIG. 2.

### Embodiment 4

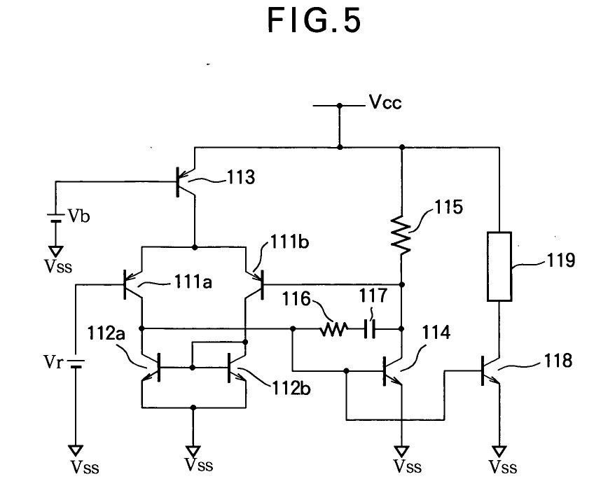

FIG. 5 shows a constant-current generating circuit according Embodiment 4 of the present invention. The circuit of FIG. 5 is similar to the circuit of FIG. 3, but bipolar transistors 111a-118 are used in place of MOSFETs 11a to 18. Specifically, PNP transistors are used in place of PMOSFETs, as transistors of a first conductivity type, and NPN transistors are used in place of NMOSFETs, as transistors of a second conductivity type. Emitters, collectors and bases of the bipolar transistors are used for connection in place of sources, drains and gates of the MOSFETs. The second power supply node in FIG. 5 is now denoted by Vcc, while the first power supply node is identified by the same reference (Vss).

The operation of the circuit of FIG. 5 is similar to that of the circuit of FIG. 3.

### Embodiment 5

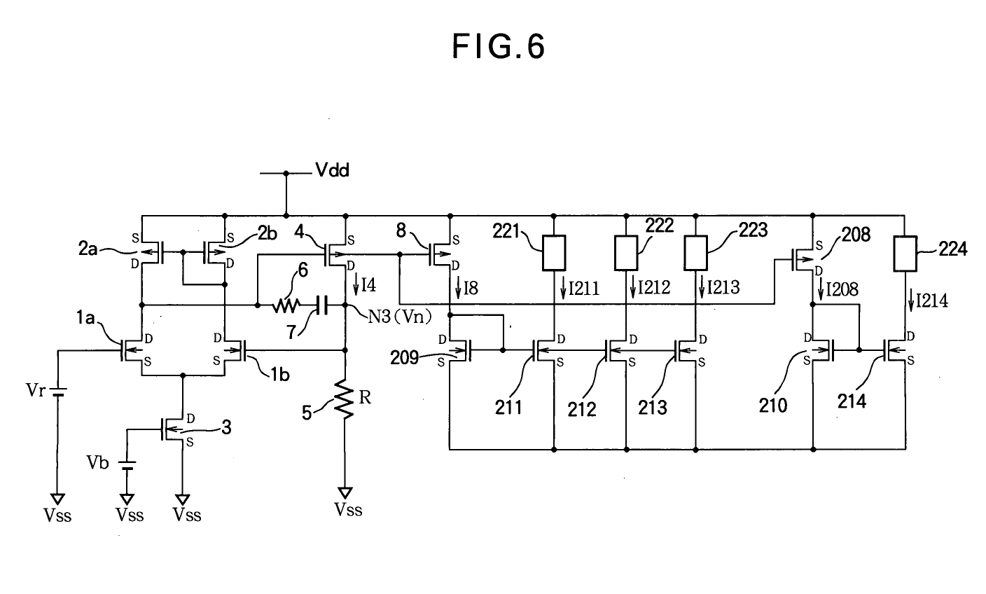

FIG. 6 shows a constant-current generating circuit according to Embodiment 5 of the present invention. The constant-current generating circuit shown in FIG. 6 is similar to the constant-current generating circuit shown in FIG. 2, and members identical to those in FIG. 2 are denoted by the same reference numerals. The constant-current generating circuit shown in FIG. 6 is additionally provided with a PMOSFET 208, NMOSFETs 209 to 214, and load circuits 221 to 224.

The PMOSFET 208 has its gate connected to the gate of the PMOSFET 4, has its source connected to the power supply node Vdd, so that the PMOSFET 208 and the PMOSFET 4 in combination form a current mirror circuit.

The NMOSFET 209 has its drain and gate connected to the drain of the PMOSFET 8, and has its source connected to the ground. The NMOSFET 209 can be regarded as a load circuit on the PMOSFET 8.

The NMOSFETs 211 to 213 have their sources connected to the ground, and have their gates connected to the gate of the NMOSFET 209. Each of the NMOSFETs 211 to 213 forms a current mirror circuit in combination with the NMOSFET 209. The load circuits 221 to 223 are respectively connected between the drains of the NMOSFETs 211 to 213 and the power supply node Vdd. The currents I211, I212 and I213 flowing through the respective load circuits 221, 222 and 223 can be controlled to be equal to the current I8 flowing through the NMOSFET 209 multiplied by the respective mirror ratios (n211, n212 and n213) of the respective current mirror circuits, i.e., the current mirror circuit formed of the NMOSFETs 211 and 209, the current mirror circuit formed of the NMOSFETs 212 and 209, and the current mirror circuit formed of the NMOSFETs 213 and 209. The current I8 flowing through the NMOSFET 209 is equal to the current I4 flowing through the PMOSFET4 multiplied by the mirror ratio n8 of the current mirror circuit formed of the PMOSFETs 4 and 8. Accordingly, the respective currents I211, I212 and I213 are given by:
I211=n8×n211×I4=n8×n211×Vr/R
I212=n8×n212×I4=n8×n212×Vr/R
I213=n8×n213×I4=n8×n213×Vr/R

The NMOSFET 210 has its drain and gate connected to the drain of the PMOSFET 208, and has its source connected to the ground. The NMOSFET 210 can be regarded as a load circuit for the PMOSFET 208.

The NMOSFET 214 has its source connected to the ground, and has its gate connected to the gate of the NMOSFET 210. The NMOSFET 214 forms a current mirror circuit in combination with the NMOSFET 210. The load circuit 224 is connected between the drain of the NMOSFET 214 and the power supply node Vdd. The current I214 flowing through the load circuit 224 can be controlled to be equal to the current I210 flowing through the NMOSFET 210 multiplied by the mirror ratio n214 of the current mirror circuit formed of the NMOSFETs 210 and 214. The current I210 flowing through the NMOSFET 210 is equal to the current I4 flowing through the PMOSFET 4 multiplied by the mirror ratio n208 of the current mirror circuit formed of the PMOSFETs 4 and 208. That is, the current I214 is given by:
I214=n208×n214×I4=n208×n214×Vr/R

In the circuit shown in FIG. 6, the currents through a plurality of load circuits 221 to 224 are controlled to be equal to the current I4 through the PMOSFET 4, multiplied by the respective mirror ratios, and are thus maintained at a constant value, and the relationship, e.g., the ratio, between the currents through the respective load circuits can be maintained constant.

Circuits similar to FIG. 6 can be formed using the circuit of FIG. 3, FIG. 4 or FIG. 5 in place of the circuit of FIG. 2.

1. A constant-current generating circuit including:
a first transistor of a first conductivity type having a first main electrode, a second main electrode, and a control electrode to which a reference potential is applied;
a second transistor of said first conductivity type having a first main electrode, a second main electrode, and a control electrode connected to an internal node;
a third transistor of a second conductivity type having a first main electrode connected to a first power supply node, a second main electrode connected to the second main electrode of said first transistor, and a control electrode connected to the second main electrode of said second transistor;
a fourth transistor of said second conductivity type having a first main electrode connected to the first power supply node, and a second main electrode and a control electrode connected to said second main electrode of said second transistor;
a fifth transistor of said first conductivity type having a first main electrode connected to a second power supply node, and a second main electrode connected to the first main electrodes of the first and second transistors;
a sixth transistor of said second conductivity type having a first main electrode connected to said first power supply node, a second main electrode connected to said internal node, and a control electrode connected to said second main electrode of said first transistor;
a reference resistor connected between said internal node and said second power supply node; and
a seventh transistor of said second conductivity type having a first main electrode connected to said first power supply node, and a second main electrode for connection with one end of a load circuit, the other end of which is connected to said second power supply node;
said seventh transistor also having a control electrode connected to said control electrode of said sixth transistor so that said sixth and seventh transistors together form a current mirror circuit.

2. The constant-current generating circuit according to claim 1, further comprising a phase compensation circuit comprising a series circuit of a resistor and a capacitor, connected between said internal node and said second main electrode of said first transistor.

3. The constant-current generating circuit according to claim 1, wherein the transistors of said first conductivity type are p-channel MOSFETs, and the transistors of said second conductivity type are n-channel MOSFETs, and said first main electrode of each transistor is a source, said second main electrode of each transistor is a drain, and said control electrode of each transistor is a gate.

4. The constant-current generating circuit according to claim 1, wherein the transistors of said first conductivity type are n-channel MOSFETs, and the transistors of said second conductivity type are p-channel MOSFETs, and said first main electrode of each transistor is a source, said second main electrode of each transistor is a drain, and said control electrode of each transistor is a gate.

5. The constant-current generating circuit according to claim 1, wherein the transistors of said first conductivity type are PNP transistors, and the transistors of said second conductivity type are NPN transistors, and said first main electrode of each transistor is an emitter, said second main electrode of each transistor is a collector, and said control electrode of each transistor is a base.

6. The constant-current generating circuit according to claim 1, wherein the transistors of said first conductivity type are NPN transistors, and the transistors of said second conductivity type are PNP transistors, and said first main electrode of each transistor is an emitter, said second main electrode of each transistor is a collector, and said control electrode of each transistor is a base.

7. The constant-current generating circuit according to claim 3, wherein
the first power supply node has a higher potential than the second power supply node.

8. The constant-current generating circuit according to claim 5, wherein
the first power supply node has a higher potential than the second power supply node.

9. The constant-current generating circuit according to claim 4, wherein
the second power supply node has a higher potential than the first power supply node.

10. The constant-current generating circuit according to claim 6, wherein
the second power supply node has a higher potential than the first power supply node.
